(19) United States
(12) Patent Application Publication
(10) Pub. No.: US 2008/0073070 A1
(43) Pub. Date: Mar. 27, 2008

(54) Highly efficient heat dissipating composite material and a heat dissipating device made of such material

(76) Inventor: Chin-Hu Kuo, Tainan City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/526,646

(22) Filed: Sep. 26, 2006

(51) Int. Cl. H05K 7/20

(52) U.S. Cl. 165/185; 361/704; 257/722

(57) ABSTRACT

A heat dissipating device made of highly efficient heat dissipating composite material consists of an aluminum heat dissipating member, and a copper heat conducting member; the aluminum heat dissipating member has many fins on one side; both the aluminum heat dissipating member and the copper heat conducting member are joined together with an alloyed interface being formed between them; each of the aluminum heat dissipating member and the copper heat conducting member has several protrusions and fitting gaps thereon, and the protrusions are fitted in corresponding fitting gap for increasing area of the alloyed interface as well as making the aluminum heat dissipating member and the copper heat conducting member grip each other.

### BACKGROUND OF THE INVENTION

1. Field of the invention

The present invention relates to a heat dissipating device made of a highly efficient heat dissipating composite material, more particularly one, which consists of an aluminum heat dissipating member, and a copper heat conducting member joined to the heat dissipating member with an alloyed interface being formed, and protrusions thereon being fitted in gaps on the heat dissipating member; thus, area of the alloyed interface and efficiency of heat transfer by conduction are increased.

2. Brief Description of the Prior Art

Chips will produce high temperature when carrying out calculation, which has to be eliminated otherwise malfunction and damage will happen to the chips. Currently, heat dissipating devices are used to rapidly eliminate high temperature produced by chips.

Referring to FIG. 1, a conventional heat dissipating device 1 consists of an aluminum heat dissipating body 11, a copper heat conducting seat 12. The aluminum heat dissipating body 11 has many dissipating fins 111 on a periphery thereof. The copper heat conducting seat 12 has good heat conductivity because it is made of copper. The copper heat conducting seat 12 is secured in the heat dissipating body 11. And, a fan is positioned right above the heat dissipating device 1. The heat dissipating device 1 is fixed on a chip such that the heat conducting seat 12 touches an upper side of the chip closely. Thus, when the chip is functioning, high temperature produced by the chip will travel rapidly to the aluminum heat dissipating body 11 through the copper heat conducting seat 12, and will be carried away by air currents produced by means of the fan.

The heat dissipating body 11 and the heat conducting seat 12 are joined together by means of carrying out heat treatment to cause alloy to form on the interface between the heat dissipating body 11 and the heat conducting seat 12. Because the heat dissipating body 11 and the heat conducting seat 12 are made of different materials, they have different coefficients of thermal expansion. Consequently, after heat treatment, the heat dissipating body 11 and the heat conducting seat 12 can't touch each other closely, and in turn the efficiency of heat transfer by conduction between heat dissipating body 11 and the heat conducting seat 12 decreases significantly, to much less than 100%.

Furthermore, because copper is relatively expensive, copper conducting seats of such heat dissipating devices are formed with relatively small thickness so that the cost reduces. Consequently, efficiency of heat transfer by conduction decreases further.

Referring to FIG. 2, another conventional heat dissipating device 2 is provided, which is an improvement on the last one 1. The heat dissipating device 2 consists of an aluminum heat dissipating body 21, a copper heat conducting seat 22. The aluminum heat dissipating body 21 has many dissipating fins 211 on an upper side thereof. The copper heat conducting seat 22 is joined to the heat dissipating body 21 by means of heat treatment, which will make alloy form on interface between the heat dissipating body 21 and the heat conducting seat 22.

Furthermore, both the aluminum heat dissipating body 21 and the copper heat conducting seat 22 are formed with a corrugated shape on their contacting sides to increase the area of contact between them; the area of contact between the corrugated sides will be approximately one point eight times that between two flat sides of the same width and length. Therefore, the heat dissipating device 2 has greater heat dissipating efficiency than the last one 1.

However, after heat treatment, the heat dissipating body 21 and the heat conducting seat 22 still can't be firmly fixed together or touch each other closely because they are made of aluminum and copper respective, which have different coefficients of thermal expansion. In addition, there isn't any means used to hold the heat dissipating body 21 and the heat conducting seat 22 firmly together. Therefore, the heat dissipating body 21 and the heat conducting seat 22 will probably fall apart, and there is still room for improvement in respect of heat dissipating efficiency.

### SUMMARY OF THE INVENTION

It is a main object of the invention to provide a kind of highly efficient heat dissipating composite material for heat dissipating devices to overcome the above problems.

The heat dissipating device of the present invention consists of an aluminum heat dissipating member, and a copper heat conducting member. The aluminum heat dissipating member has many fins on one side. Both the aluminum heat dissipating member and the copper heat conducting member are joined together with an alloyed interface being formed between them. Each of the heat dissipating member and the heat conducting member has several protrusions and fitting gaps thereon, and the protrusions are fitted in corresponding fitting gaps. Therefore, area of contact between the heat dissipating member and the heat conducting member is increased, and the heat dissipating member and the heat conducting member closely touch and grip each other without possibility of falling apart, thus increasing efficiency of heat transfer by conduction between the heat dissipating member and the copper heat conducting member.

### BRIEF DESCRIPTION OF THE DRAWINGS

The present invention will be better understood by referring to the accompanying drawings, wherein:

FIG. 1 is a side view of the first prior art,

FIG. 2 is a side view of the second prior art,

FIG. 3 is an exploded perspective view of the first highly efficient heat dissipating composite material in the present invention,

FIG. 4 is a side view of the first composite material,

FIG. 5 is an exploded front view of the second composite material,

FIG. 6 is a rear view of the second composite material,

FIG. 7 is an exploded perspective view of a heat dissipating device made of the first composite material,

FIG. 8 is a side view of a heat dissipating device made of the first composite material,

FIG. 9 is an exploded front view of a heat dissipating device made of the second composite material,

FIG. 10 is a rear view of a heat dissipating device made of the second composite material,

FIG. 11 is an exploded perspective view of another heat dissipating device made of the first composite material, and

FIG. 12 is a top view of another heat dissipating device made of the first composite material.

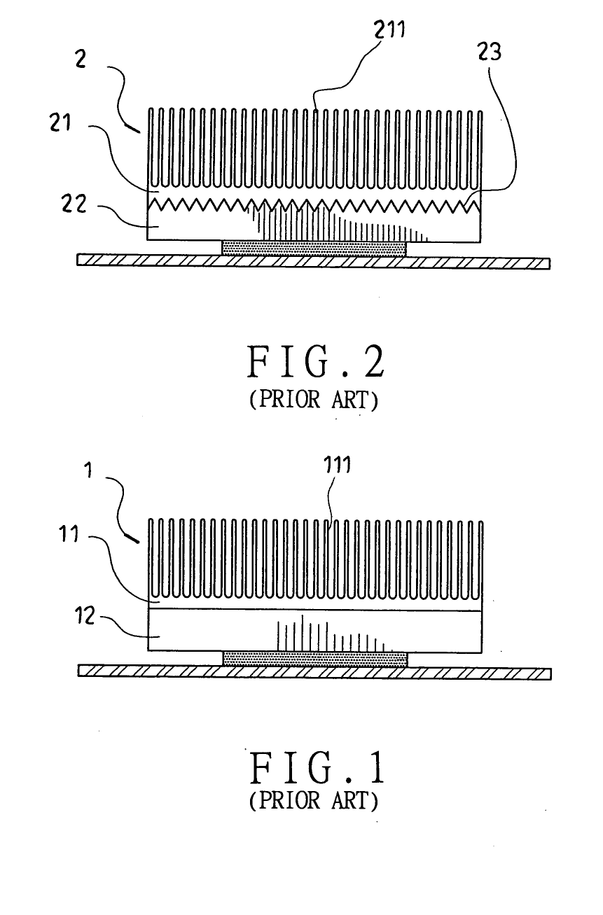

### DETAILED DESCRIPTION OF THE PREFERRED EMBODIMENTS

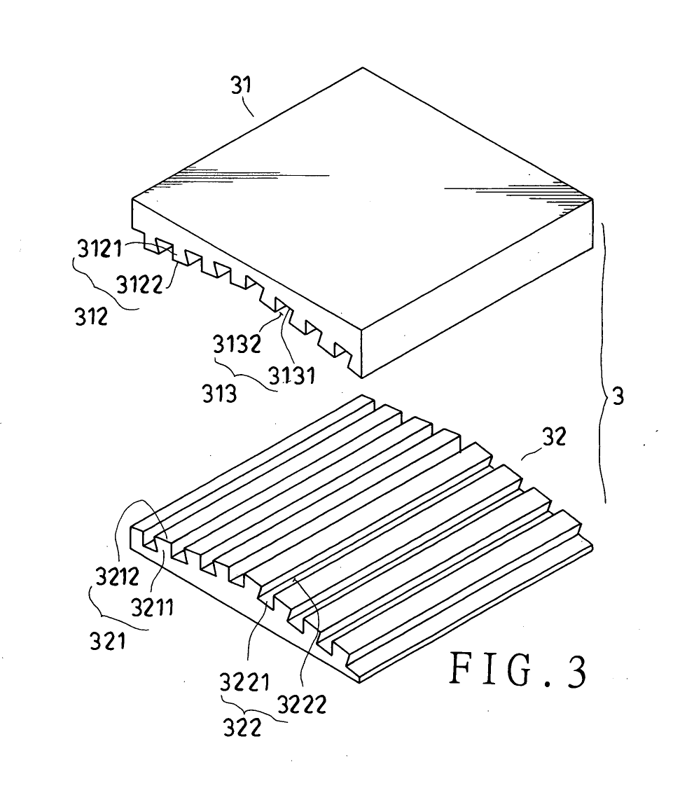

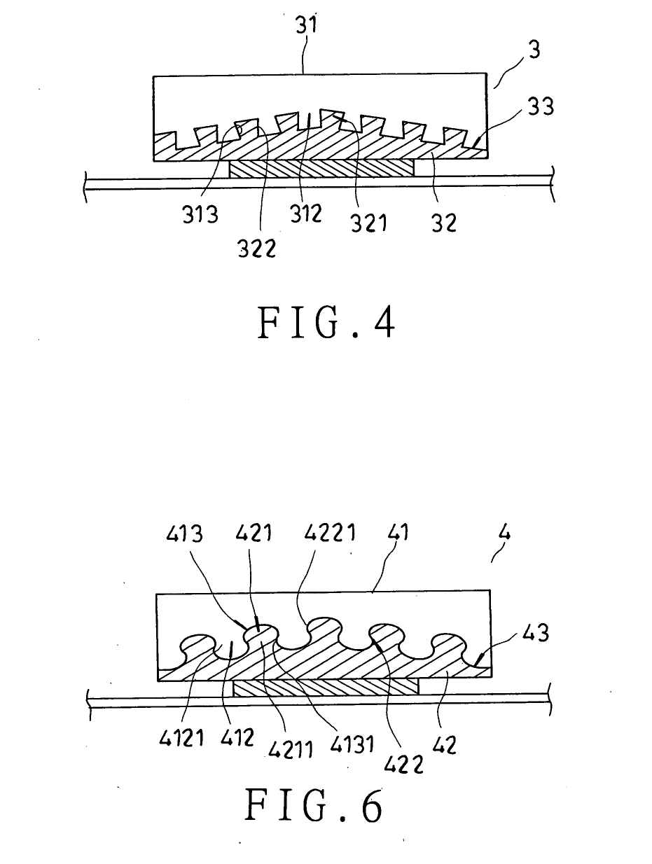

Referring to FIGS. 3 and 4, a first preferred embodiment of a highly efficient heat dissipating composite material 3 consists of an aluminum heat dissipating member 31, and a copper heat conducting member 32. The aluminum heat dissipating member 31 is positioned over and secured to the copper heat conducting member 32 with an interface 33 forming between a lower side of the aluminum heat dissipating member 31 and an upper side of the copper heat conducting member 32. And, the interface 33 slopes gradually down from a middle portion to a periphery thereof. The heat dissipating member 31 has several lengthways extending protrusions 312 on its lower side, which have a trapezoid shape; each of the lengthways extending protrusions 312 has a neck portion 3121, and a free end 3122, and the neck portion 3121 is narrower than the free end 3122. The heat dissipating member 31 has a fitting gap (sunken portion) 313 between every two adjacent ones of the lengthways extending protrusions 312, which fitting gap 313 has a trapezoid shape; each of the fitting gaps 313 has an inner end 3131, and an opening 3132 narrower than the inner end 3131. The heat conducting member 32 has several lengthways extending protrusions 321 on its upper side, which have a trapezoid shape; each of the lengthways extending protrusions 321 has a neck portion 3211, and a free end 3212, and the neck portion 3211 is narrower than the free end 3212. The heat conducting member 32 has a fitting gap (sunken portion) 322 between every two adjacent ones of the lengthways extending protrusions 321, which fitting gap 322 has a trapezoid shape; each of the fitting gaps 322 has an inner end 3221, and an opening 3222 narrower than the inner end 3221. The aluminum heat dissipating member 31 is joined to the copper heat conducting member 32 with the trapezoid shaped protrusions 312 being fitted in the fitting gaps 322, and the trapezoid shaped protrusions 321 being fitted in the fitting gaps 313; owing to the shape of the trapezoid shaped protrusions 312, 321, and the fitting gaps 313, 322, the heat dissipating member 31 and the heat conducting member 32 will grip and closely touch each other, and it is impossible for the heat dissipating member 31 and the heat conducting member 32 to move relative to each other or fall apart in Y-axis direction. Furthermore, the heat dissipating member 31 and the heat conducting member 32 are secured together by means of carrying out heat treatment to cause formation of alloy on the interface 33 between them. Consequently, there is high efficiency of heat transfer by conduction between the heat dissipating member 31 and the heat conducting member 32.

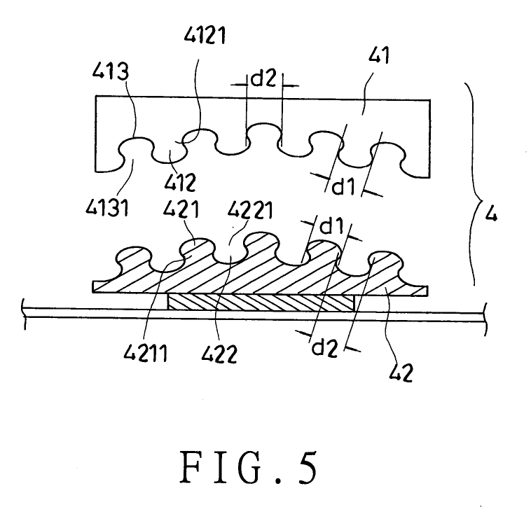

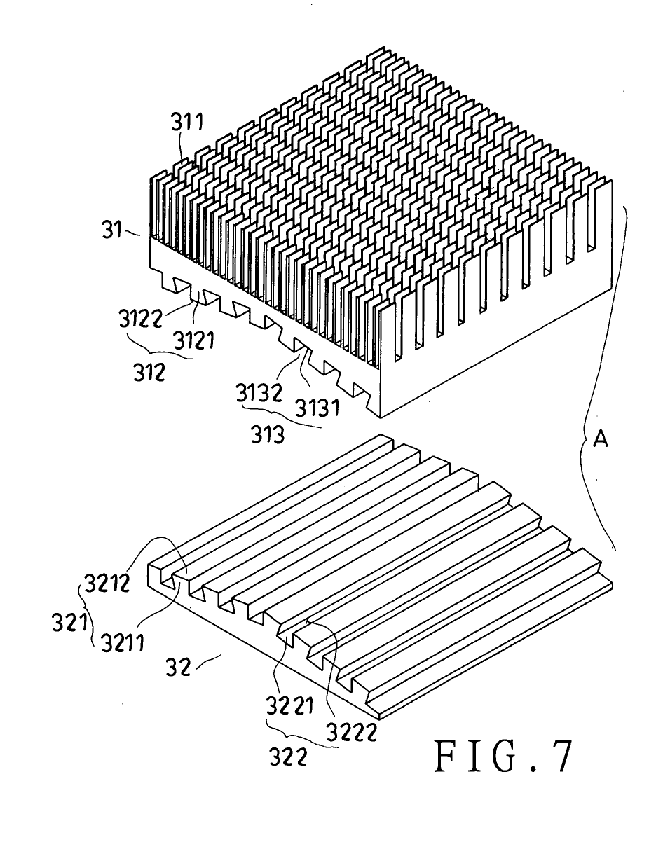

Referring to FIGS. 5 and 6, a second preferred embodiment of a highly efficient heat dissipating composite material 4 consists of an aluminum heat dissipating member 41, and a copper heat conducting member 42. The heat dissipating member 41 is positioned over and secured to the heat conducting member 42 with an interface 43 forming between a lower side of the heat dissipating member 41 and an upper side of the heat conducting member 42. And, the interface 43 slopes gradually down from a middle portion to a periphery thereof. The heat dissipating member 41 has several convexly curved protrusions 412 on its lower side, each of which has a neck portion 4121 smaller than a greatest diameter (d1) thereof. The heat dissipating member 41 has a concavely curved fitting gap 413 between every two adjacent ones of the convexly curved protrusions 412; each of the fitting gaps 413 has an opening 4131 smaller than a greatest diameter (d2) thereof. The copper heat conducting member 42 has several convexly curved protrusions 421 on its upper side, each of which has a neck portion 4211 smaller than a greatest diameter (d1) thereof. The heat conducting member 42 has a concavely curved fitting gap 422 between every two adjacent ones of the convexly curved protrusions 421; each of the fitting gaps 422 has an opening 4221 smaller than a greatest diameter (d2) thereof. The aluminum heat dissipating member 41 is joined to the copper heat conducting member 42 with the convexly curved protrusions 412 being fitted in the concavely curved fitting gaps 422, and the convexly curved protrusions 421 being fitted in the concavely curved fitting gaps 413; because of the shape of the convexly curved protrusions 412, 421 and the concavely curved fitting gaps 413, 422, the heat dissipating member 41 and the heat conducting member 42 will grip and closely touch each other, and it is impossible for the heat dissipating member 41 and the heat conducting member 42 to move relative to each other or fall apart in Y-axis direction. Furthermore, the heat dissipating member 41 and the heat conducting member 42 are secured together by means of carrying out heat treatment to alloy the interface 43 between them.

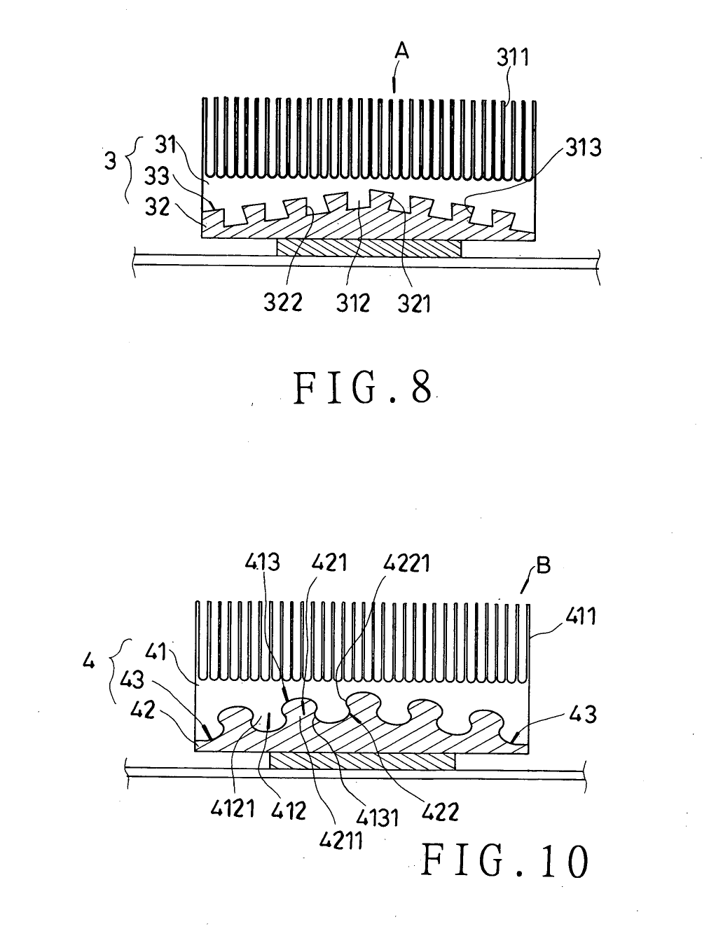

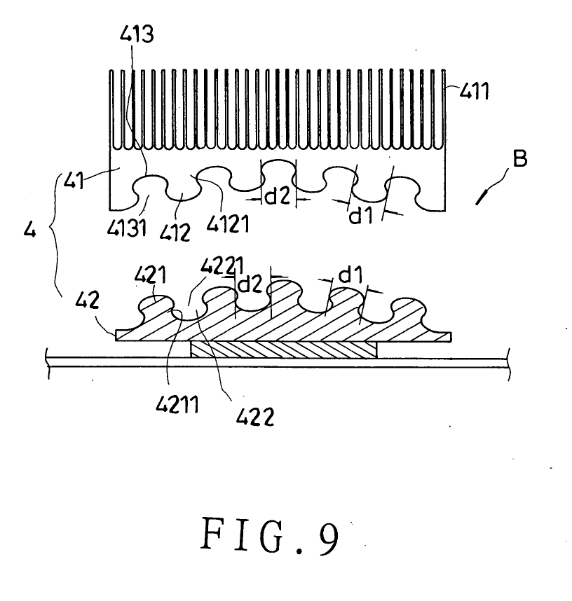

Referring to FIGS. 7 and 8, a heat dissipating device (A) is made of the highly efficient heat dissipating composite material 3 (the first preferred embodiment), and its aluminum heat dissipating member 31 is further formed with many heat dissipating fins 311 on an upper side thereof for increasing heat dissipating efficiency. Referring to FIGS. 9 and 10, a heat dissipating device (B) is made of the highly efficient heat dissipating composite material 4 (the second preferred embodiment), and its aluminum heat dissipating member 41 is further formed with many heat dissipating fins 411 on an upper side thereof.

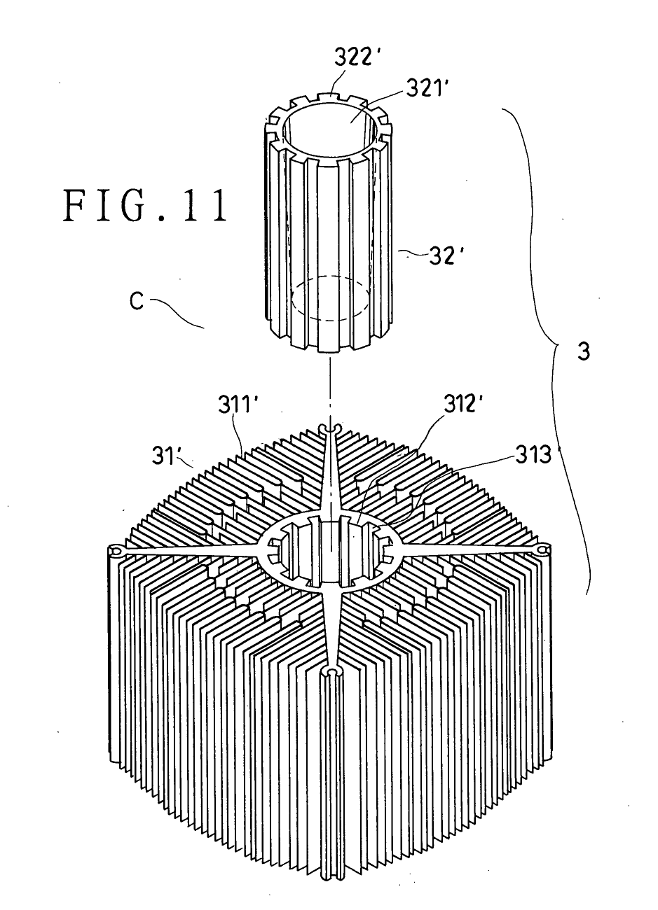

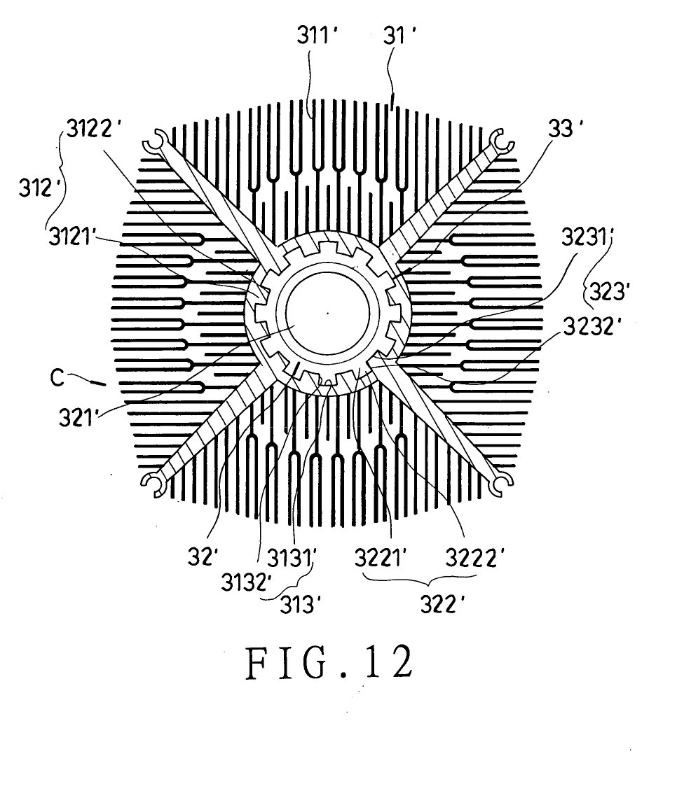

Referring to FIGS. 11 and 12, another heat dissipating device (C) is made of the highly efficient heat dissipating composite material 3 (the first preferred embodiment). The heat dissipating device (C) consists of an aluminum heat dissipating member 31′, and a copper heat conducting member 32′. The heat dissipating member 31′ is hollow cylindrical, and has many heat dissipating fins 311′ on an outer side thereof. The heat conducting member 32′ is in the shape of a post, and is inserted in the heat dissipating member 31′ with an interface 33′ forming between an inner side of the heat dissipating member 31′ and an outward side of the heat conducting member 32′. A hollow portion 321′ is formed on a middle of the heat conducting member 32′, which hollow portion 321′ has an opening at an upper end; thus, volume and weight of the heat conducting member 32′ are reduced. The upper end of the hollow portion 321′ is wider than a lower end of the hollow portion 321′. The heat dissipating member 31′ has several lengthways extending protrusions 312′ on its inner side, which have a trapezoid shape; each of the protrusions 312′ has a neck portion 3121′, and a free end 3122′, and the neck portion 3121′ is narrower than the free end 3122′. The heat dissipating member 31′ has a fitting gap 313′ between every two adjacent lengthways extending protrusions 312′, which fitting gap 313′ has a trapezoid shape; each fitting gap 313′ has an inner end 3131′ and an opening 3132′ narrower than the inner end 3131′. The heat conducting member 32′ has lengthways extending protrusions 322′ on its outward side, which have a trapezoid shape; each of the lengthways extending protrusions 322′ has a neck portion 3221′, and a free end 3222′ wider than the neck portion 3221′. The heat conducting member 32′ has a fitting gap 323′ between every two adjacent lengthways extending protrusions 322′, which fitting gap 323′ has a trapezoid shape; each fitting gap 323′ has an inner end 3231′, and an opening 3232′ narrower than the inner end 3221. The heat dissipating member 31′ is joined to the heat conducting member 32′ with the trapezoid shaped protrusions 312′ being fitted in the fitting gaps 323′, and the trapezoid shaped protrusions 322′ being fitted in the fitting gaps 313′; owing to the shape of the trapezoid shaped protrusions 312′, 322′, and the fitting gaps 313′, 323′, the heat dissipating member 31′ and the heat conducting member 32′ will grip and closely touch each other. Furthermore, the heat dissipating member 31′ and the heat conducting member 32′ are secured together by means of carrying out heat treatment to alloy the interface 33′ between them. Consequently, there is high efficiency of heat transfer by conduction between the heat dissipating member 31′ and the heat conducting member 32′.

Because efficiency of heat transfer is in direct proportion to the area of contact between the heat conducting member and the heat dissipating member of the heat dissipating composite material, and the heat conducting member has spaced apart concavities thereon, and the heat dissipating member has spaced apart protrusions tightly fitted in respective ones of the concavities to make the heat conducting member and the heat dissipating member closely touch and grip each other, the area of contact between the heat conducting member and the heat dissipating member is relatively large. Consequently, efficiency of heat transfer by conduction between the heat conducting member and the heat dissipating member is improved, and the heat dissipating device has relatively high heat dissipating efficiency.

From the above description, it can be seen that the present invention has the following advantages:

1. Area of contact (the alloyed interface) between the heat dissipating member and the heat conducting member increases because the heat dissipating member and the heat conducting member have protrusions and sunken portions (gaps) on their surfaces, and are joined together with the protrusions being fitted in the concavities. Therefore, efficiency of heat transfer and dissipation is significantly improved.

2. The protrusions of the heat dissipating member and the heat conducting member are formed with such a shape that their free ends are wider than their neck portions. Therefore, after the heat dissipating member and the heat conducting member are joined together with the protrusions being fitted in the corresponding sunken portions, they will closely touch and grip each other without possibility of falling apart.

3. The copper heat conducting member is formed with a hollow portion on the middle, and the hollow portion is formed with an opening at its upper end. Therefore, volume and weight of the copper heat conducting member are reduced, saving material cost without having to reduce area of the alloyed interface between the heat dissipating member and the heat conducting member.

What is claimed is:

1. A highly efficient heat dissipating composite material, comprising
an aluminum heat dissipating member, and
a copper heat conducting member, the aluminum heat dissipating member and the copper heat conducting member being joined together with an alloyed interface being formed between them;
each of the aluminum heat dissipating member and the copper heat conducting member having a plurality of protrusions and fitting gaps thereon; the aluminum heat dissipating member and the copper heat conducting member gripping each other with the protrusions being fitted in corresponding fitting gaps.

2. The highly efficient heat dissipating composite material as recited in claim 1, wherein the interface between the aluminum heat dissipating member and the copper heat conducting member slopes gradually down from a middle portion to a periphery thereof.

3. The highly efficient heat dissipating composite material as recited in claim 2, wherein the protrusions of the heat dissipating member and the heat conducting member have a trapezoid shape, and the fitting gaps are provided between every two adjacent protrusions, and have a trapezoid shape; the heat dissipating member and the heat conducting member being joined together with the trapezoid shaped protrusions of the heat dissipating member being fitted in the trapezoid shaped fitting gaps of the heat conducting member, and the trapezoid shaped protrusions of the heat conducting member being fitted in the trapezoid shaped fitting gaps of the heat dissipating member.

4. The highly efficient heat dissipating composite material as recited in claim 3, wherein each of the trapezoid shaped protrusions has a neck portion, and a free end wider than the neck portion thereof, and each of the trapezoid shaped fitting gaps has an opening narrower than an inner end thereof.

5. The highly efficient heat dissipating composite material as recited in claim 2, wherein the protrusions of the heat dissipating member and the heat conducting member are convexly curved, and the fitting gaps are provided between every two adjacent protrusions, and are concavely curved; the heat dissipating member and the heat conducting member being joined together with the convexly curved protrusions of the heat dissipating member being fitted in the concavely curved fitting gaps of the heat conducting member, and with the convexly curved protrusions of the heat conducting member being fitted in the concavely curved fitting gaps of the heat dissipating member.

6. The highly efficient heat dissipating composite material as recited in claim 5, wherein each of the convexly curved protrusions has a neck portion smaller than a greatest diameter thereof, and each of the concavely curved fitting gaps has an opening smaller than a greatest diameter thereof.

7. A heat dissipating device made of a highly efficient heat dissipating composite material, comprising
an aluminum heat dissipating member having a plurality of heat dissipating fins on one side; and
a copper heat conducting member, the aluminum heat dissipating member and the copper heat conducting member being joined together with an alloyed interface being formed between them;
each of the aluminum heat dissipating member and the copper heat conducting member having a plurality of protrusions and fitting gaps thereon; the aluminum heat dissipating member and the copper heat conducting member gripping each other with the protrusions being fitted in corresponding fitting gaps.

8. The heat dissipating device made of a highly efficient heat dissipating composite material as recited in claim 7, wherein the interface between the aluminum heat dissipating member and the copper heat conducting member slopes gradually down from a middle portion to a periphery thereof.

9. The heat dissipating device made of a highly efficient heat dissipating composite material as recited in claim 8, wherein the protrusions of the heat dissipating member and the heat conducting member have a trapezoid shape, and the fitting gaps are provided between every two adjacent protrusions, and have a trapezoid shape; the heat dissipating member and the heat conducting member being joined together with the trapezoid shaped protrusions of the heat dissipating member being fitted in the trapezoid shaped fitting gaps of the heat conducting member, and the trapezoid shaped protrusions of the heat conducting member being fitted in the trapezoid shaped fitting gaps of the heat dissipating member.

10. The heat dissipating device made of a highly efficient heat dissipating composite material as recited in claim 9, wherein each of the trapezoid shaped protrusions has a neck portion, and a free end wider than the neck portion thereof, and each of the trapezoid shaped fitting gaps has an opening narrower than an inner end thereof.

11. The heat dissipating device made of a highly efficient heat dissipating composite material as recited in claim 8, wherein the protrusions of the heat dissipating member and the heat conducting member are convexly curved, and the fitting′ gaps are provided between every two adjacent protrusions, and are concavely curved; the heat dissipating member and the heat conducting member being joined together with the convexly curved protrusions of the heat dissipating member being fitted in the concavely curved fitting gaps of the heat conducting member, and the convexly curved protrusions of the heat conducting member being fitted in the concavely curved fitting gaps of the heat dissipating member.

12. The heat dissipating device made of a highly efficient heat dissipating composite material as recited in claim 11, wherein each of the convexly curved protrusions has a neck portion smaller than a greatest diameter thereof, and each of the concavely curved fitting gaps has an opening smaller than a greatest diameter thereof.

13. The heat dissipating device made of a highly efficient heat dissipating composite material as recited in claim 7, wherein the aluminum of the heat dissipating member is hollow cylindrical, and has plural heat dissipating fins on an outer side thereof, and the copper heat conducting member is in a shape of a post, and inserted in the heat dissipating member.

14. The heat dissipating device made of a highly efficient heat dissipating composite material as recited in claim 13, wherein the copper heat conducting member has a hollow portion on a middle thereof, and the hollow portion has an opening at an upper end.

15. The heat dissipating device made of a highly efficient heat dissipating composite material as recited in claim 14, wherein an upper end of the hollow portion is wider than a lower end of the hollow portion.

16. The heat dissipating device made of a highly efficient heat dissipating composite material as recited in claim 8, wherein the protrusions of the heat dissipating member and the heat conducting member have a trapezoid shape, and the fitting gaps are provided between every two adjacent protrusions, and have a trapezoid shape; the heat dissipating member and the heat conducting member being joined together with the trapezoid shaped protrusions of the heat dissipating member being fitted in the trapezoid shaped fitting gaps of the heat conducting member, and the trapezoid shaped protrusions of the heat conducting member being fitted in the trapezoid shaped fitting gaps of the heat dissipating member.

17. The heat dissipating device made of a highly efficient heat dissipating composite material as recited in claim 16, wherein each of the trapezoid shaped protrusions has a neck portion, and a free end wider than the neck portion thereof, and each of the trapezoid shaped fitting gaps has an opening narrower than an inner end thereof.
